(19) United States
(12) Patent Application Publication
(10) Pub. No.: US 2008/0053521 A1
(43) Pub. Date: Mar. 6, 2008

(54) Method of dicing polycrystalline silicon solar cell wafer

(75) Inventors: Jer-Liang Andrew Yeh, Hsinchu (TW); Ming-Sung Yang, Hsinchu (TW); Chien-Hsien Lee, Hsinchu (TW); Wen-Ching Hsu, Hsinchu (TW); Ya-Lan Ho, Hsinchu (TW)

Correspondence Address: TROXELL LAW OFFICE PLLC, SUITE 1404, 5205 LEESBURG PIKE, FALLS CHURCH, VA, 22041, US

(73) Assignee: Sino-American Silicon Products Inc

(21) Appl. No.: 11/797,913

(22) Filed: May 8, 2007

(30) Foreign Application Priority Data
May 10, 2006 (TW) 095116586

(51) Int. Cl. H01L 31/036

(52) U.S. Cl. 136/256; 136/258

(57) ABSTRACT

A method to dice polycrystalline silicon into solar cell wafer by following grain growth direction of crystal so to allow larger grains to present on a surface of the solar cell wafer to reduce the grain number per unit area on the surface of the solar cell wafer and/or photo transfer interface; i.e., to reduce potential barrier and resistance created among grains; whereas extra foreign matters in the boundary will compromise photo transfer efficiency and electronic migration capability of the substrate surrounding the boundary, reduced number of boundary in turn upgrade photo transfer efficiency.

### BACKGROUND OF THE INVENTION

(a) Field of the Invention

The present invention is related to a solar cell wafer dicing technology, and more particularly to an improved method of dicing polycrystalline silicon solar cell wafer for reducing grain number per unit area on surface of solar cell wafer and/or photo transfer interface thus to upgrade photo transfer efficiency.

(b) Description of the Prior Art

As a member in the family of semi-conductors, solar photocell is also known as solar cell wafer. Silicon represents those materials commonly used for production of solar cell. The working principle for power generation involves converting solar energy into electric energy. There are various types of materials for production of wafer of solar PV (Photovoltaic) cell and can be roughly classified into two groups, respectively, mono-crystalline silicon, polycrystalline/multi-crystalline silicon, amorphous silicon, and other non-silicon materials. Wherein, mono-crystalline silicon, polycrystalline/multi-crystalline silicon are most commonly used. Composition atoms of the mono-crystalline silicon are arranged in a given rule to yield higher product transfer efficiency; however, the production cost is comparatively more expensive. Though the mono-crystalline silicon products dominated earlier in the market; high production cost of mono-crystalline silicon product, and rapid development of polycrystalline silicon to significantly upgrade its transfer efficiency give polycrystalline silicon the advantage of lower cost. Accordingly, the polycrystalline silicon is exiting the mono-crystalline silicon.

In the manufacturing process of solar cell wafer using polycrystalline silicon, liquid raw material for grain growth is placed in crucible and in numerous crystal seeds C1 are formed on the bottom of the crucible; those crystal seeds C1 are then consolidated in a single direction to upward grow to form an integral polycrystalline silicon 10 as illustrated in FIGS. 1 and 2 of the accompanying drawings to be followed with process of dicing, grinding, polishing, and slicing into a substrate in a given size for further production of solar cell wafer.

FIGS. 2 through 4 show the dicing process flow of the entire wafer substrate as found in the current solar cell wafer manufacturing technology. The entire polycrystalline silicon 10 is cut into N equal parts depending on the size desired; e.g., into 16 equal parts of crystal 11, and then into multiple substrates 12 in a given thickness of wafer in radial, i.e., at right angle to the crystal 11. Whereas the polycrystalline silicon 10 is of polycrystalline structure a boundary exists between two grains A, multiple wafer substrates 12 are diced by following radial of the polycrystalline silicon 10. The dicing direction is vertical to the grain growth direction of the crystal seed and multiple boundaries are distributed in the wafer substrate 12 and on its surface as illustrated in FIG. 4; therefore, comparatively higher numbers of grain A and boundary B present on the wafer substrate completed using the dicing method of the prior art.

In the event that the wafer indicates multi-crystalline microstructure, incomplete crystal structure will be resulted due to the boundary between grains to produce potential barrier. As the resistance to the transmission of electrons among grains increases, the conductivity of the microstructure decreases. Once the potential barrier rises to a given setting, electrons are forced to accumulate on the boundary instead of passing through the boundary. In addition, the boundary reduces photo transfer efficiency and electronic migration capability of the substrate surrounding the boundary. Accordingly, when applied in an electronic product, amperage flux is lower, thus to compromise photo transfer efficiency.

### SUMMARY OF THE INVENTION

The primary purpose of the present invention is to provide a modified method for dicing polycrystalline silicon into solar cell wafers to reduce grain number per production unit and to overcome the failure of the solar cell wafer to reach its expected results.

To achieve the purpose, the present invention discloses a method of dicing the crystalline along the grain growth direction for producing solar cell wafer. Larger grains present on the surface of the solar cell wafer to reduce the grain number per unit area on the surface of the solar cell wafer and/or photo transfer interface; i.e., to reduce potential barrier and resistance created among grains. Whereas extra foreign matters in the boundary will compromise photo transfer efficiency and electronic migration capability of the substrate surrounding the boundary, reduced number of boundary in turn upgrade photo transfer efficiency.

### BRIEF DESCRIPTION OF THE DRAWINGS

FIG. 1 is a schematic view showing a general structure of polycrystalline silicon.

FIG. 2 is a schematic view showing a method for dicing polycrystalline silicon of general structure into wafers.

FIG. 3 is a schematic view showing a method of the prior art for dicing a crystal into multiple wafers.

FIG. 4 is a schematic view showing grains and grain boundaries in a crystal of the prior art.

FIG. 5 is a schematic view showing a crystal is diced into strips using a method of the present invention.

FIG. 6 is a schematic view showing grains and grain boundaries in a crystal of the present invention.

FIG. 7 is a schematic view showing another method of the present invention for dicing polycrystalline silicon into multiple crystals.

FIG. 8 is a schematic view of another method yet of the present invention for dicing polycrystalline silicon into multiple strips of crystal.

FIG. 9 is a schematic view showing a wafer substrate diced using the method of the prior art.

FIG. 10 is a schematic view showing a wafer substrate diced using the method of the present invention.

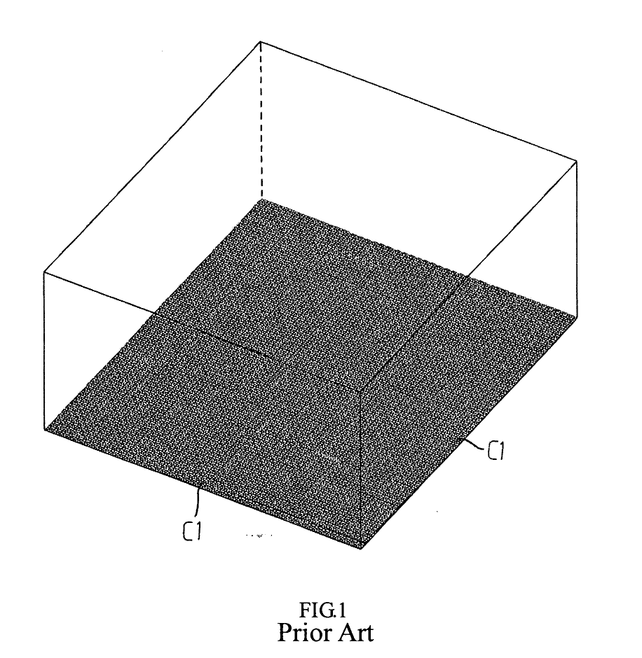

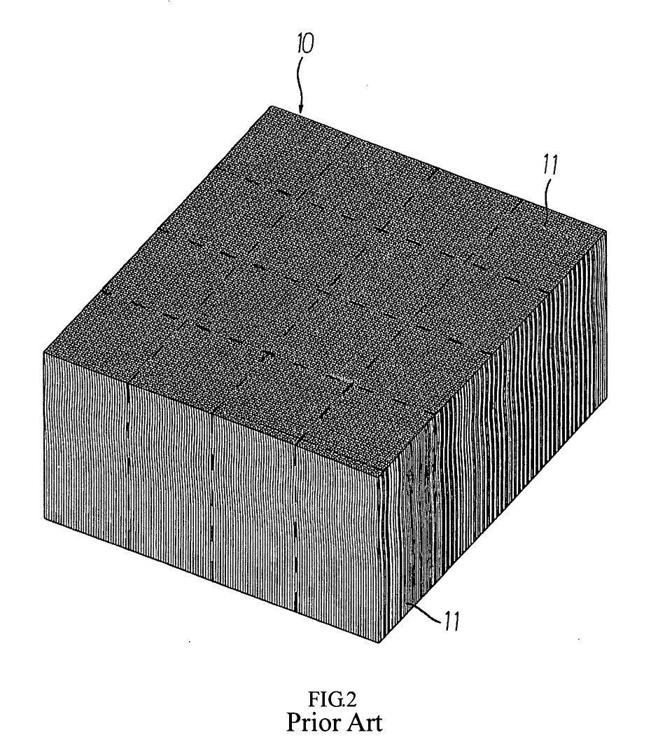

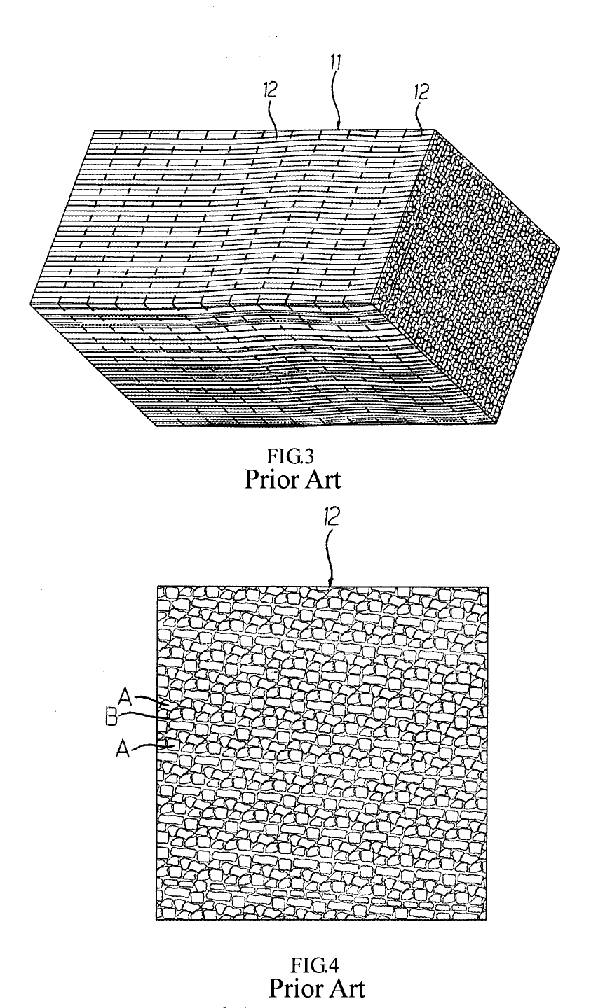

### DETAILED DESCRIPTION OF THE PREFERRED EMBODIMENTS

A method to dice polycrystalline silicon into solar cell wafer of the present invention is essentially provided to solve the problem of compromised photo transfer rate and electronic migration capacity of accumulated electrons on both sides of grain boundary that fail to pass the grain boundary since there is comparatively higher boundary number among grains present on the surface of and in the wafer substrate completed with dicing process using a method of the prior art.

Whereas there are many types of materials available for manufacturing polycrystalline solar cell wafer, polycrystalline silicon is essentially selected for multiple preferred embodiments of the present invention; and a crystal produced using the polycrystalline silicon is characterized in that the crystal is full of multiple grains as illustrated in FIG. 5 forming along its growth direction into a long axis and a short axis and multiple boundaries among grains; and the crystal is then given dicing, grinding, polishing, and slicing processes to produce multiple wafer substrates with each in a given size for production of solar cell wafer.

The present invention creates higher value of the polycrystalline solar cell wafer for industrial use by achieving a breakthrough of conventional method of dicing the polycrystalline silicon into solar cell wafer is essentially comprised of dicing the polycrystalline silicon into by following the grain growth direction into solar cell wafer so that larger grains present on the surface of the solar cell wafer in reducing grain number on the surface of the solar cell wafer and/or photo transfer interface. Potential barrier and resistance created on grain boundary is reduced on the wafer substrate availed from using the dicing method of the present invention. Since extra foreign matters found in the boundary will compromise photo transfer efficiency and electronic migration capability of the substrate surrounding the grain boundary, reduced grain boundary number upgrades photo transfer efficiency.

The wafer substrate dicing method of the present invention is comprised of the following steps:

a. A crystal 11 is preset to be cut into multiple wafer substrates 12′ with each in a given size as illustrated in FIG. 5;

b. The crystal 11 is diced into multiple wafer substrates 12′ by following the grain growth direction; and in the preferred embodiment, the crystal 11 is diced into four wafer substrates; and

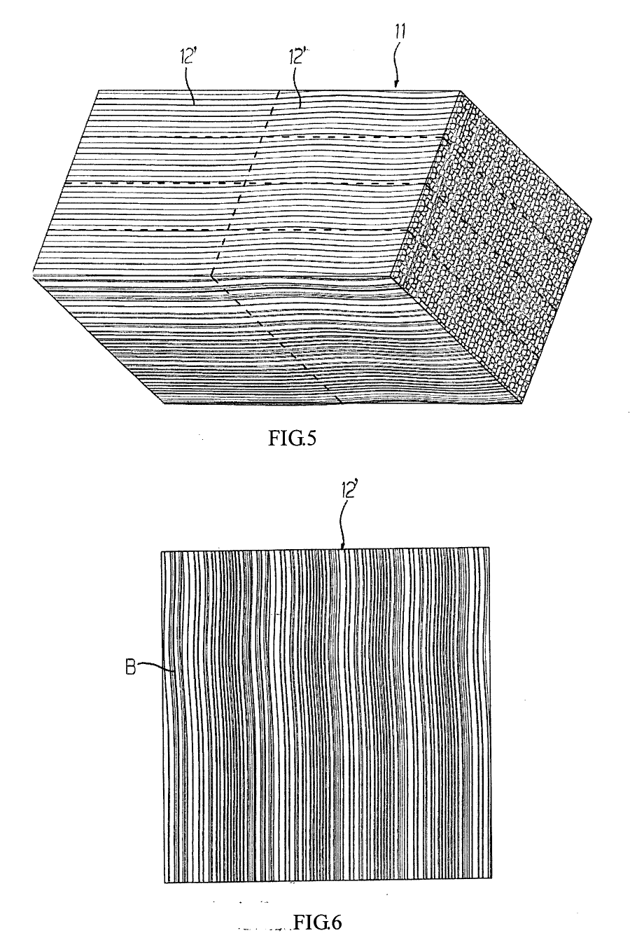

c. A finished product of a solar cell wafer is available as illustrated in FIG. 6.

Whereas a long axis and a short axis are formed along the grain growth direction, another dicing method of the present invention is comprised of the following steps:

a. A crystal 11 is preset to be cut into multiple wafer substrates 12′ with each in a given size;

b. Multiple wafer substrates as desired are diced along the long-axis of the grain growth direction; and

c. A finished product of a solar cell wafer is available as illustrated in FIG. 6.

The dicing method of the present invention permits significant reduction of grain boundary number. FIG. 4 shows a sectional view of a wafer substrate processed using a conventional dicing method, and FIG. 6 shows a wafer substrate diced using a method of the present invention. By comparison, it is obviously that both numbers of grain A and grain boundary B per unit area of the wafer substrate processed with the dicing method of the present invention are less than those found with the wafer substrate processed using the conventional dicing method; thus the significantly reduced grain boundary per production unit area of the wafer substrate using the dicing method of the present invention permits significantly reduced grain boundary ratio in the wafer substrate completed with subsequent cutting.

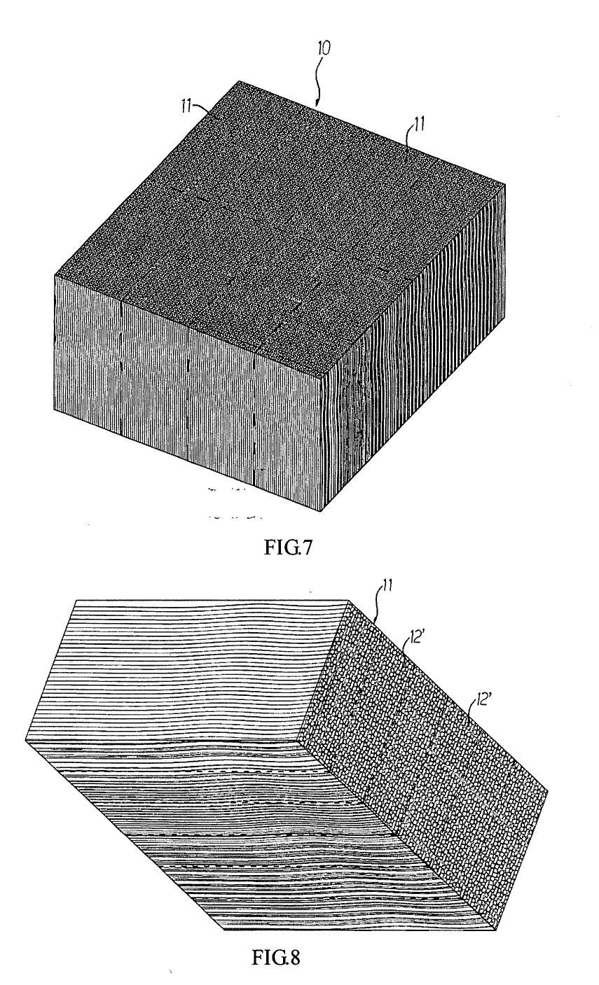

Furthermore, as illustrated in FIG. 7, the polycrystalline silicon 10 is cut into eight equal parts of the crystal 11 as illustrated in FIG. 7 with each part roughly indicating a rectangle. Similarly, the crystal 11 is cut into multiple wafer substrates 12′ with each in a given size as illustrated in FIG. 8 by following the grain growth direction for production of solar cell wafer. The grain boundary number in the wafer substrate finished with the dicing process is also significantly reduced. Of course, the polycrystalline silicon when molded in a crucible may be directly formed into the size and shape of the crystal and then forthwith diced into the wafer substrate for production of the solar cell wafer.

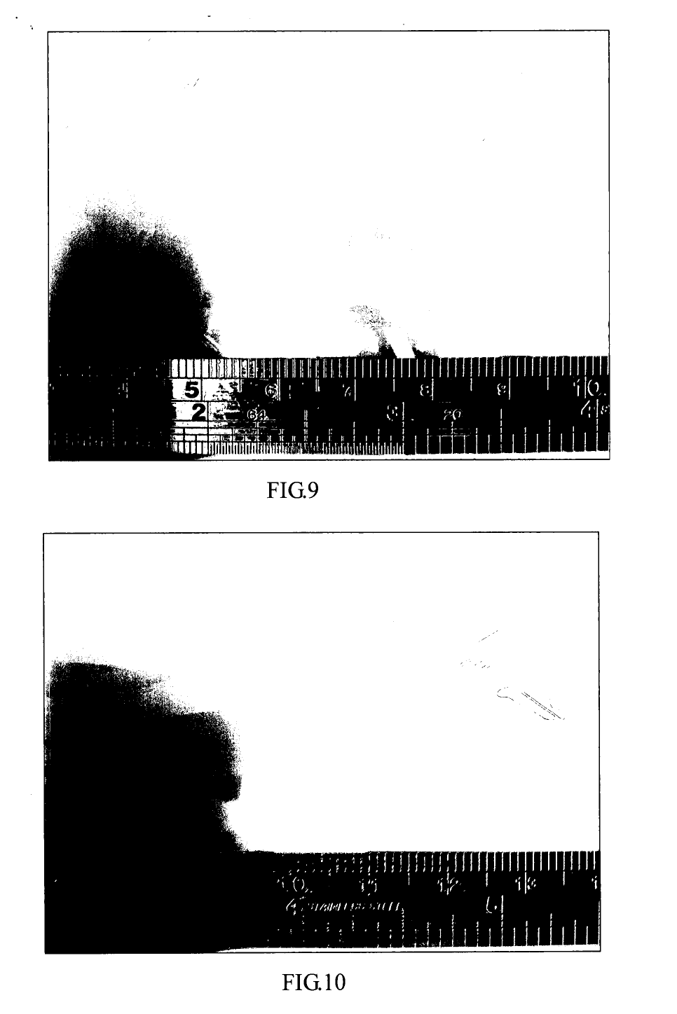

FIG. 9 shows a wafer substrate diced using a method of the prior art and FIG. 10 shows a wafer substrate diced using the method of the present invention. By taking the same production unit area for comparison, the number of the boundary B of the wafer substrate formed using the dicing method of the present invention is less than that of the wafer substrate diced using the method of the prior art to significantly reduce the grain boundary number of the entire substrate, leading to significantly reduced number of grain in the wafer substrate completed with the subsequent cutting.

Whereas characteristics demonstrated by the extent of potential barrier produced by the grain boundary vary, resistance presents on the entire microstructure that prevents easy passing through of electrons driven by electric field. As the concentration of ions in the grain boundary increases to produce sufficiently high potential barrier, it takes comparatively high energy for electrons to pass through the grain boundary. When the potential barrier and belt of the grain boundary diffuses in the grain boundary of high concentration of ions, higher potential barrier presents, and even those electrons are prevented from passing through the grain boundary and are forced to accumulate on both sides of the grain boundary as a result of precipitation of secondary phase. Accordingly when applied in an electronic product, the flux of amperage gets smaller and the grain boundary will compromise photo transfer efficiency and electronic migration capability of the substrate surrounding the grain boundary.

Therefore, the boundary number in the wafer substrate diced using the method of the present invention is significantly reduced to further reduce potential barrier created by the boundary while upgrading power of generation due to reduced boundary number.

The prevent invention provides an improved method to dice polycrystalline silicon for reducing boundary number on wafer substrate completed with the dicing thus to effectively reduce the capacity characteristics of the wafer substrate, and the application for a patent is duly filed accordingly. However, it is to be noted that the preferred embodiments disclosed in the specification and the accompanying drawings are not limiting the present invention; and that any construction, installation, or characteristics that is same or similar to that of the present invention should fall within the scope of the purposes and claims of the present invention.

I claim,

1. A method to dice polycrystalline silicon into solar cell wafer by following grain growth direction for producing multiple solar cell wafers for larger grains to present on a surface of each solar cell wafer.

2. A method to dice polycrystalline silicon into solar cell wafer by following a long axial direction of the grain for producing multiple solar cell wafers for larger grains to present on a surface of each solar cell wafer.

3. A method to dice polycrystalline silicon into solar cell wafer including the following steps:
a. Crystal in a given size is formed;
b. The crystal is diced into multiple wafer substrates with each in a given size by following the grain growth direction; and
c. The solar cell wafers are completed with the production.

4. The method to dice polycrystalline silicon into solar cell wafer as claimed in claim 1, wherein the crystal is preset to be diced into multiple equal parts of wafer substrate.

5. The method to dice polycrystalline silicon into solar cell wafer as claimed in claim 2, wherein the crystal is preset to be diced into multiple equal parts of wafer substrate.

6. The method to dice polycrystalline silicon into solar cell wafer as claimed in claim 1, wherein the crystal of polycrystalline silicon is directly formed in a given size when molded in the crucible.

7. The method to dice polycrystalline silicon into solar cell wafer as claimed in claim 2, wherein the crystal of polycrystalline silicon is directly formed in a given size when molded in the crucible.

8. The method to dice polycrystalline silicon into solar cell wafer as claimed in claim 3, wherein the crystal of polycrystalline silicon is directly formed in a given size when molded in the crucible.
